(19) United States
(12) Patent Application Publication
(10) Pub. No.: US 2006/0077734 A1
(43) Pub. Date: Apr. 13, 2006

(54) Direct mapped repair cache systems and methods

(76) Inventor: John Y. Fong, Allen, TX (US)

Correspondence Address: TEXAS INSTRUMENTS INCORPORATED, P O BOX 655474, M/S 3999, DALLAS, TX, 75265, US

(21) Appl. No.: 11/230,405

(22) Filed: Sep. 20, 2005

Related U.S. Application Data
(60) Provisional application No. 60/614,947, filed on Sep. 30, 2004.

(51) Int. Cl. G11C 29/00

(52) U.S. Cl. 365/200

(57) ABSTRACT

The present invention facilitates memory devices and operation thereof by employing a repair cache system 600 to correct or repair identified faulty memory locations. The repair cache system 600 includes a repair verification router that compares a memory address 604 for a read/write request to a list or series of repair locations 608. On identifying a matching repair location, a repair register 616 located within a repair register bank 615 is coupled to a data bus 626. Otherwise, a memory location within the main memory 630 and addressed by the memory address 604 is coupled to the data bus 626.

### FIELD OF THE INVENTION

The present invention relates generally to memory devices, and more particularly, to systems and methods for repairing/replacing faulty memory cells in memory devices.

### BACKGROUND OF THE INVENTION

Storage capacities of semiconductor memory devices continue to increase while dies on which the memory devices are fabricated continue to decrease. As a result, the number of memory cells present in memory devices and the complexity of the memory devices continues to increase as well. Additional memory cells and complexity require additional sense amplifiers, charge supply circuitry, addressing mechanisms, decoders, and the like. Further, the dimensions of components and/or structures present in memory devices necessarily shrink in response to the additional storage capacity. As a consequence, memory cells of memory devices can be more sensitive to defects, residues, and contaminants than memory cells of prior, smaller storage capacity memory devices. Such defects and contaminants can cause memory cells to be inoperable and unusable.

One technique to mitigate defects and contaminants and reduce the number of resulting defective cells is by tighter semiconductor fabrication process control and layout design/architecture. However, the ever-shrinking dimensions and increase in storage capacity can counteract the benefits of tighter process control and improvements in layout design/architecture. As a result, a significant number of memory devices are fabricated that include one or more defective memory cells. Without some type of correction mechanism, such memory devices can be unusable and/or introduce errors by their use.

One type of correction mechanism is to fabricate a number of redundant rows for memory devices. The number of redundant rows are formed in addition to original rows of memory cells. Then, during testing faulty memory cells and associated rows are identified. Subsequently, a selection device such as a fuse based device is employed to allow redundant rows to replace identified defective rows. As a result, addressing to memory cells in the original rows is rerouted to the replacement, redundant rows of memory cells. Thus, defective memory cells/rows are not apparent to external devices.

Another type of correction mechanism is to fabricate a number of redundant columns for memory devices in addition to original columns of memory cells. Defective or faulty memory cells/columns are then identified during testing. Subsequently, associated columns are replaced by one or more of the redundant columns by utilizing a selection mechanism such as a fuse based device. Accordingly, addressing to memory cells located in defective/faulty columns is rerouted to assigned redundant columns of memory cell. These defective memory cells/columns are not known to external devices.

One problem with the above correction mechanisms, redundant row replace and redundant column replace, is that large numbers of non-faulty cells can be needlessly replaced. For example, a single faulty memory cell, under a redundant row mechanism, requires that the row containing the single faulty memory cell be replaced. A single row in a memory device can have a large number of memory cells present, such as 512 or 1024 memory cells. Thus, one faulty memory cell can cause the other cells in the row, such as 511 or 1023, to be replaced. Such inefficiencies can reduce the storage capacity of memory devices by consuming valuable space on dies in order to provide for redundant rows and/or columns.

### SUMMARY OF THE INVENTION

The following presents a simplified summary in order to provide a basic understanding of one or more aspects of the invention. This summary is, not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention facilitates memory devices and operation thereof by employing a repair cache system to correct or repair identified faulty memory locations. The repair cache system can be employed to repair individual faulty memory locations instead of requiring full rows and/or columns to be repaired. Repair locations are associated with identified faulty memory locations of a main memory. Repair registers referenced by the repair locations can then be employed for memory operations instead of the faulty memory locations.

In one aspect, a repair cache system includes a repair verification router that compares a memory address for a read/write request to a list or series of repair locations. On identifying a matching repair location, a repair register located within a repair register bank is coupled to a data bus. Otherwise, a memory location within the main memory and addressed by the memory address is coupled to the data bus. Other systems and methods are disclosed.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1A is a diagram illustrating random, isolated defects that can result from chemical mechanical planarization.

FIG. 1B is a diagram illustrating random, isolated defects that can result from via and contact voids during memory device fabrication.

FIG. 1C is a diagram that depicts formation of a blister in an exemplary semiconductor device.

FIG. 2A is a diagram illustrating a memory array of some non-volatile memory and random defects therein.

FIG. 2B is a diagram illustrating a non-volatile memory cell.

FIG. 3A is a diagram illustrating repair row correction mechanisms.

FIG. 3B is a diagram illustrating repair column correction mechanisms.

FIG. 3C is a diagram illustrating block repair correction mechanisms.

FIG. 4 is a diagram illustrating operation of a set associative repair cache in accordance with an aspect of the present invention.

FIG. 5 is a block diagram illustrating a repair cache system in accordance with an aspect of the present invention.

FIG. 6 is a block diagram illustrating a direct mapped repair cache system in accordance with an aspect of the present invention.

FIG. 7 is a diagram illustrating an exemplary repair register bank in accordance with an aspect of the present invention.

FIG. 8 is a diagram illustrating an exemplary row repair in accordance with an aspect of the present invention.

FIG. 9 is a flow diagram illustrating a method 900 of operating a direct mapped repair cache in accordance with an aspect of the present invention.

FIG. 10 is a flow diagram illustrating a method 1000 of configuring a repair cache system in accordance with an aspect of the present invention.

### DETAILED DESCRIPTION OF THE INVENTION

The present invention will now be described with respect to the accompanying drawings in which like numbered elements represent like parts. The figures provided herewith and the accompanying description of the figures are merely provided for illustrative purposes. One of ordinary skill in the art should realize, based on the instant description, other implementations and methods for fabricating the devices and structures illustrated in the figures and in the following description.

The present invention facilitates memory devices and operation thereof by employing a repair cache system to correct or repair identified faulty memory locations. The repair cache system can be employed to repair individual faulty memory locations instead of requiring full rows and/or columns to be repaired. Repair locations are associated with identified faulty memory locations of a main memory. Repair registers referenced by the repair locations can then be employed for memory operations instead of the faulty memory locations. As a result, efficiencies and space savings can be obtained.

Redundant rows of memory, redundant columns of memory, and redundant blocks of memory are commonly employed to recover from faulty/defective memory cells. Faulty columns and/or rows that respectively contain one or more faulty memory cells are identified during testing. Then, the faulty columns and/or rows are “corrected” or replaced by an identical number of redundant rows and/or columns. If, for example, entire rows of memory cells are faulty, replacement of the rows by redundant rows is relatively efficient. However, if only a single memory cell within a row is faulty, replacement of the entire row by a redundant row is relatively inefficient.

Some fabrication induced, large area defects can impact large portions of rows, columns, or blocks. For such large area defects, row, column, and/or block replacement mechanisms can be relatively efficient and practical. However, other fabrication defects include random, isolated defects that affect a small, isolated number of memory cells (e.g., one). For these random isolated defects, row, column, and/or block replacement mechanisms are relatively inefficient.

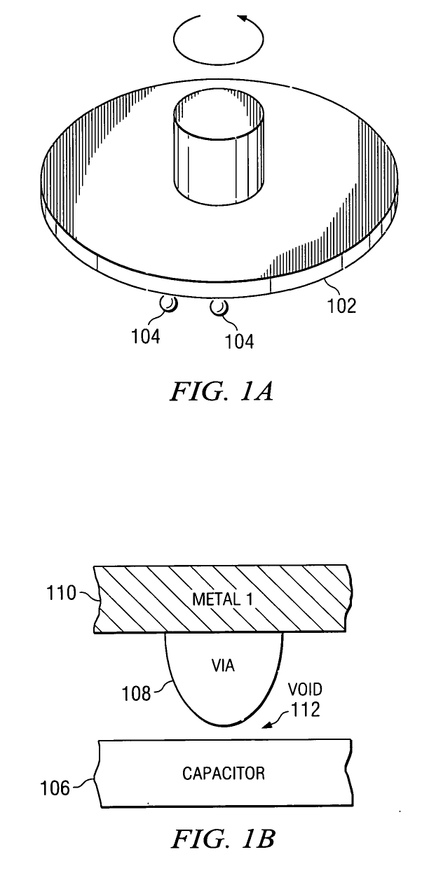

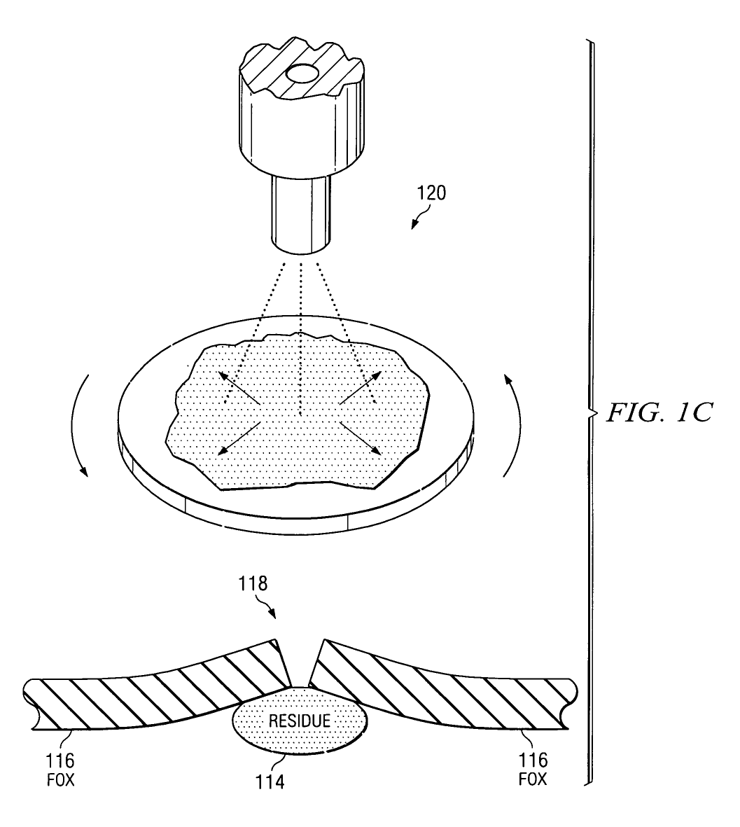

FIG. 1A is a diagram illustrating random, isolated defects that can result from chemical mechanical planarization (CMP). Some layers formed on semiconductor devices can require a flattening, polishing layer operation in order to promote uniformity and to permit additional layers to be formed thereon. This flattening and polishing operation is referred to as planarization. One common type of planarization is the CMP process, which employs a rotating head 102 positioned on a rotating wafer in an opposite direction. A slurry flows across the wafer surface as the head and wafer rotated. The slurry includes chemicals and particles that facilitate planarization of the wafer. However, the slurry and/or the CMP head can undesirably include residue 104 that causes isolated, random damage to the wafer and memory devices formed thereon. The residue 104 can, for example, abrasively contact metal layers resulting in scratches and/or missing metal, leading to unwanted open circuits and/or increased resistance. The random damage can result in random, isolated defects and, as a consequence, random, isolated, faulty memory cells.

FIG. 1B is a diagram illustrating random, isolated defects that can result from via and contact voids during memory device fabrication. Via formation and metallization are commonly performed during memory device fabrication in order to provide electrical connection to capacitors and other structures present within memory devices. However, vias or plugs can be defective in that they are not completely filled or that they were etched improperly thereby not properly connecting underlying structures. As an example, FIG. 1B shows a capacitor 106, a via 108, and a metal interconnect layer 110. In this example, the via 108 was not properly filled and, as a result, there is a void 112 present that breaks or prevents connection from the capacitor 106 to the via 108 and, therefore the metal interconnect layer 110. The void 112 can cause failure of a single memory cell by preventing access to the capacitor 106, but does not generally impact neighboring memory cells. As a result, the void 112 creates a random, isolated defect.

FIG. 1C is a diagram illustrating random, isolated defects that can result from etch or CMP residue during memory device fabrication. Etching processes are commonly performed during memory device fabrication, particularly with respect to capacitor formation and metallization. Etch residue from etch processes, such as plasma etching, can remain after completion of the etch process. Additionally, residue from planarization processes can also remain after completion. Subsequently formed layers cover the residue thereby trapping the residue. The formed layers become malformed or distorted as a result. Planarization processes, such as CMP, can damage the distorted layers by sheering off protruding crests, referred to as blisters.

FIG. 1C is a diagram that depicts formation of a blister in an exemplary semiconductor device. An etch process is performed that leaves undesired etch residue 114 on the device. A field oxide layer 116, in this example, is formed and distorted due to the presence of the residue 114. A metal layer deposition and planarization process 120 are then performed that results in formation of a blister 118 that breaks the field oxide layer 116. The blister 118 can lead to shorting and/or other problems and result in faulty memory cells.

The blisters, such as the blister 118, are a result of the undesired etch residue that remains after etching. The residue is typically randomly distributed. As a result, the blisters formed, and therefore the memory cells impacted, are also randomly distributed.

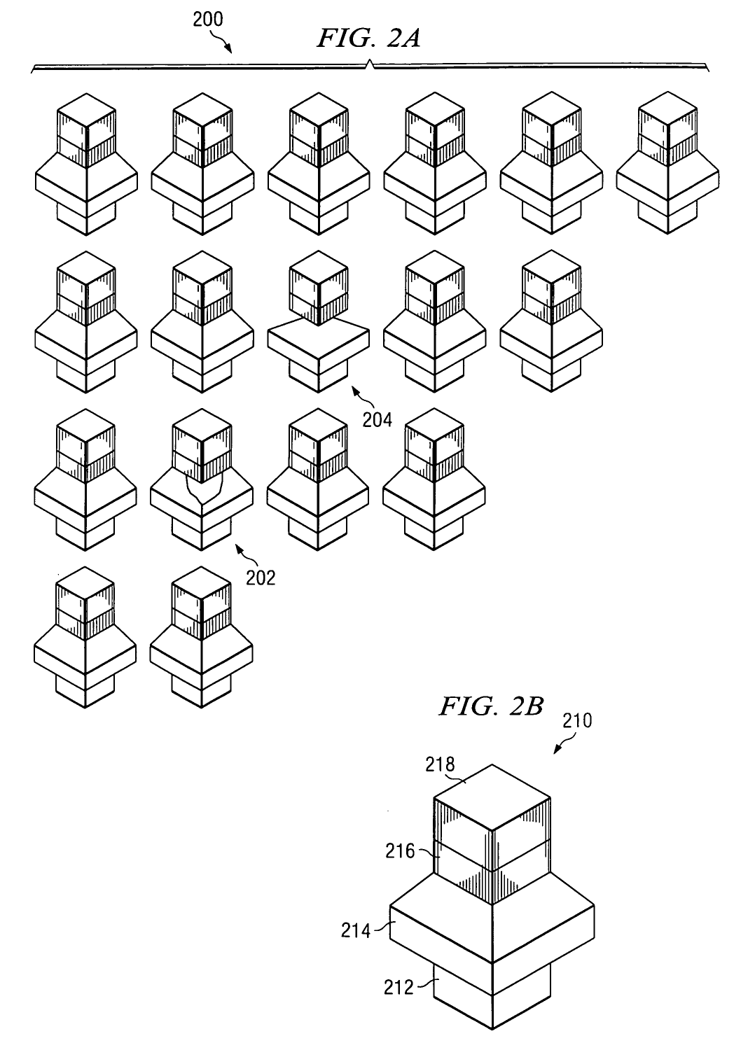

FIG. 2A is a diagram illustrating an exemplary memory array 200 having some non-volatile memory and random defects therein. The memory array 200 can be comprised of nonvolatile memories such as ferroelectric memory (FeRAM), Magnetoresistive Random Access Memory (MRAM), and Ovonic Unified Memory (OUM). These memories include new layers for memory elements that exist between a substrate and upper metal layers that therefore have a high probability of being damages by CMP or etch process residues that can result in random, isolated bit failures. The newer non-volatile memories contain electrodes and special films or layers for electric fields, magnetic fields, and/or simple resistance. Random defects to these electrode layers or special films or layers are potential sources for weak or faulty bits, which likely are isolated random defects not efficiently solved by replacing entire rows, columns, and/or blocks. These defects can result from CMP processes, etching and leaving residues, plasma etching and leaving residues, forming oxide layers and leaving residues, forming other layers and leaving residues, and the like and can introduce open circuits into the electrodes and/or special layers.

FeRAM utilize ferroelectric capacitors that possess two characteristics required for a nonvolatile memory cell, that is to have two stable states corresponding to the two binary levels in a digital memory, and to retain their states without electrical power.

MRAM is a method of storing data bits using magnetic charges instead of the electrical charges used by DRAM (dynamic random access memory). A metal is defined as magnetoresistive if it shows a slight change in electrical resistance when placed in a magnetic field. By combining the high speed of static RAM and the high density of DRAM, proponents say MRAM could be used to significantly improve electronic products by storing greater amounts of data, enabling it to be accessed faster while consuming less battery power than existing electronic memory.

OUM uses thin-film materials to store information economically and with excellent solid-state memory properties. The thin-film material is a phase-change chalcogenide alloy similar to the film used to store information on commercial CD-RW and DVD-RAM optical disks.

Optical memory disks use laser light to write small spots by converting the thin film back and forth from amorphous (disordered atomic structure) to crystalline (regular, highly repetitive, and ordered atomic structure). The digital data of 1s and 0s are stored as amorphous (high resistance and non-reflective) or crystalline (low resistance and reflective) structures. OUM devices store data in a similar manner but use electrical energy controlled by small transistors to electronically convert the material to crystalline or to amorphous (thus a 1 or a 0). This electronic solid-state memory stores data in a much smaller area and with higher speeds for both read and write than its optical counterpart.

The operating speed of OUM memory technology is similar to DRAM and many orders of magnitude faster than Flash write. Also, unlike conventional Flash memory, OUM memory is fully random accessible for memory addressing. Any given bit can be uniquely addressed and then written or read by the customer. Further, Flash memory “wears out” (fails) after about 100,000 write cycles, while the OUM memory state can be written more than about 10 trillion times, making this memory useful for program storage (Flash) as well as general purpose interactive (DRAM) data storage memory.

The memory array 200 is illustrated with two defective memory cells 202 and 204. Defects to special films present in the memory cells cause the cells 202 and 204 to improperly operate, thereby being defective or faulty.

FIG. 2B is a diagram illustrating a non-volatile memory cell 210. The memory cell 210 is of a more recent design such as FeRAM, OUM, and MRAM. The memory cell 210 includes a lower electrode 212, a special film 214, an upper electrode 216, and an extra via 218. The special film 214 has properties dependent on the type of memory (e.g., ferroelectric, magnetoresistive, phase-change ability) and can be sensitve to random defects. The special film 214, if damaged, only impacts the memory cell 210 and does not negatively impact other or surrounding memory cells. Similarly, damage to the lower electrode 212 and the upper electrode is limited to the memory cell 210.

The above figures and descriptions illustrate examples of some types of random defects that can occur in semiconductor device fabrication as appreciated by the inventor of the present invention that lead to random, isolated memory cell or bit failures. Some other types of random defects include oxide defects, blisters, missing metal/conductive material, CMP scratches, and CMP residue.

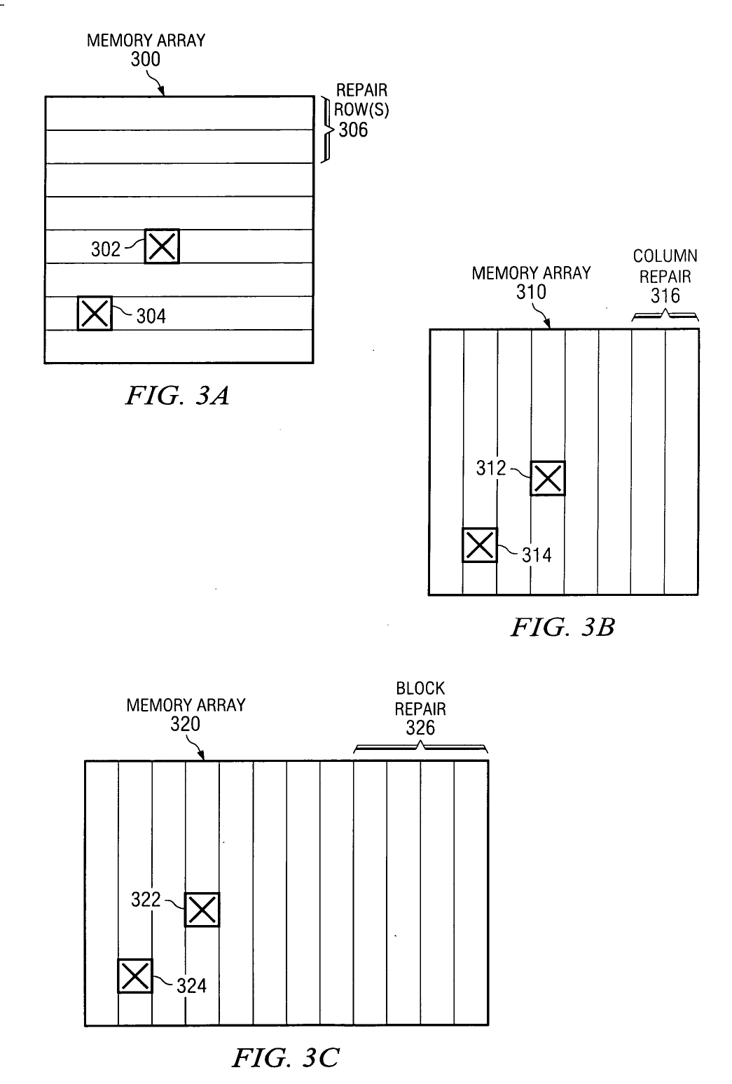

FIG. 3A is a diagram illustrating repair row correction mechanisms. A memory array 300 is shown comprised of a number of rows of memory cells/bits. Testing identifies first and second faulty memory cells 302 and 304 within the array 300. Redundant repair rows 306 are employed to replace the rows containing the faulty memory cells 302 and 304. A typical row in a memory device includes 1024 memory cells. Therefore, a single defective memory cell requires 1024 memory cells to be replaced. This type of replacement is relatively inefficient because other cells in the replaced rows were not defective.

FIG. 3B is a diagram illustrating repair column correction mechanisms. Here, a memory array 310 is comprised of a number of columns of memory cells/bits. Testing has identified first and second faulty memory cells 312 and 314 within the array 310. Under this correction mechanism, redundant repair columns 316 replace both columns comprising the first and second faulty memory cells 312 and 314. Typical columns are about 512 memory cells tall. Thus, in this example, replacement of a single faulty memory cell requires replacement of 512 memory cells (of which 511 are not defective). Again, this correction mechanism is relatively inefficient for isolated random defects because a large number of cells were replaced that operated correctly.

FIG. 3C is a diagram illustrating block repair correction mechanisms. A memory array 320 is comprised of blocks of memory cells. Respective blocks are comprised of a fixed number of rows and columns. In order to correct a defective memory cell, an entire block comprising the defective/faulty memory cell is replaced. Testing identified first and second faulty memory cells 302 and 304. In order to correct the identified faulty memory cells 302 and 304, two redundant blocks of memory cells 326 are employed. Once again, this correction mechanism is relatively inefficient as a large number of properly working memory cells are unnecessarily replaced.

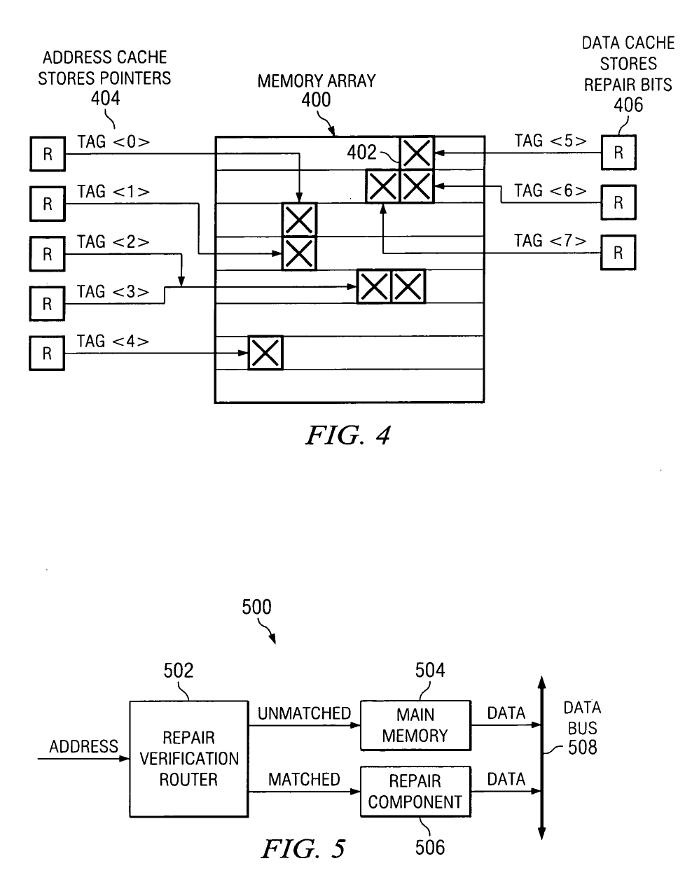

FIG. 4 is a diagram illustrating operation of a repair cache in accordance with an aspect of the present invention. The repair cache is operative to repair/correct faulty memory cells including those that result from random, isolated defects in a relatively efficient manner.

FIG. 4 shows a memory array 400 comprised of a number of rows and columns. Due to random, isolated defects incurred during fabrication, such as those described supra, a number of faulty memory cells 402 are present. Typically, testing is performed that includes reading and writing to cells within the memory array 400, wherein cells that fail to properly store and maintain correct values are deemed faulty. A repair cache system of the present invention is operable to efficiently repair/correct the faulty memory cells 402.

Respective faulty memory locations 402 are replaced by repair data locations 406, also referred to as repair resources and/or repair locations, on a one for one basis. The repair data locations can store a varied number of bits such as, for example, 1 bit, 8 bits, 16 bits, 32 bits, and the like. It is noted that the repair data locations can be a single memory cell. The faulty memory locations can, likewise, respectively comprise a varied number of bits or a single memory cell. It is further noted that memory cells can be single bit memory cells or multi bit memory cells (e.g., 2 or more bits). Addresses to the faulty memory cells 402 are redirected towards the replacement data caches by address caches 404 that store pointers to the replacement data caches 406. As a result, only a single memory cell or small number of memory cells can be employed to correct a defective memory cell and is, therefore, typically more efficient than row replacement, column replacement, and/or block replacement mechanisms for random, isolated defects.

The repair cache of the present invention differs from typical, conventional memory caches. The repair cache of the present invention maintains a list of only identified faulty memory addresses and includes separate repair resources aside from a main memory or array. In contrast, a conventional memory cache only maintains a list of cached memory addresses and does not maintain separate resources for the cached addresses. Furthermore, the conventional memory cache stores data from a main memory whereas the repair cache of the present invention replaces data from a main memory.

FIG. 5 is a block diagram illustrating a repair cache system 500 in accordance with an aspect of the present invention. The system 500 is operable to correct for faulty memory cells by having redundant memory cells located in a repair component. The redundant memory cells are accessed instead of the faulty memory cells within a main memory for read/write operations. By employing repair locations, faulty memory cells located within main memory can be accounted for while mitigating the number of redundant memory cells required to do so.

The repair cache system 500 includes a repair verification router 502, a main memory 504, a repair component 506, and a data bus 508. The verification router 502 receives memory addresses for read/write operations and routes the request to the main memory 504 or the repair component 506. The verification router 502 can comprises tables, data structures, pointers, comparators, and other components that facilitate determining which component to route the request to. The main memory 504 comprises volatile and/or non-volatile memory locations, each of which can comprise one or more memory cells (e.g., a word of memory). The memory locations of the main memory 504 are identified as faulty or valid by a suitable testing mechanism, as described below. It is appreciated that suitable testing mechanisms can be employed and yet mistakenly identify valid memory locations.

The main memory 504 can be of a suitable memory type including, but not limited to, ferroelectric memory, magnetoresisteve random access memory, ovonic unified memory, dynamic random access memory, and the like. The repair component 506 is also comprises volatile and/or non-volatile memory locations, each of which can comprise one or more memory cells (e.g., a 32 bits). The repair component 506 can also be of a suitable memory type including, but not limited to, ferroelectric memory, magnetoresisteve random access memory, ovonic unified memory, dynamic random access memory, and the like.

Initially, the main memory 504 is tested and/or scanned to identify zero or more faulty memory locations within the main memory 504. The faulty memory locations include 1 or more memory cells of which at least one memory cells is determined to be faulty. A number of suitable mechanisms can be employed to identify faulty memory cells and, therefore, faulty memory locations. One example of a suitable mechanism is to write selected patterns of data to memory cells, read patterns of data from the memory cells, and then compare the read patterns to the written patterns to identify faulty memory cells. Another example of a suitable mechanism is to repeatedly perform cycles of writing a first value to memory cells and then read back from the memory cells expecting the first value to be read back and then writing a second value, to the memory cells and then reading back from the memory cells expecting the second value to be read back. Other suitable mechanisms of identifying faulty memory locations can be employed.

After identifying the faulty memory locations, a number of repair locations in a repair component 506 are assigned to the faulty memory locations, typically on a one to one basis. The repair locations can then be employed instead of the faulty memory locations during device operation. Addresses for the faulty memory locations and corresponding pointers to the repair locations are typically generated and provided to the verification router 502.

For read/write operations, the repair verification router 502 receives a memory address and determines whether the memory address matches a repair location. If a match is identified, the matching repair location of the repair component 506 is provided access to the data bus 508 for read and/or write access. Otherwise, if the memory address is unmatched, a memory location within main memory 504 is provided access to the data bus 508 for read and/or write access. Subsequently, content from the repair location or memory location can be obtained from the data bus for a read operation or placed on the data bus and written to the repair location or memory location.

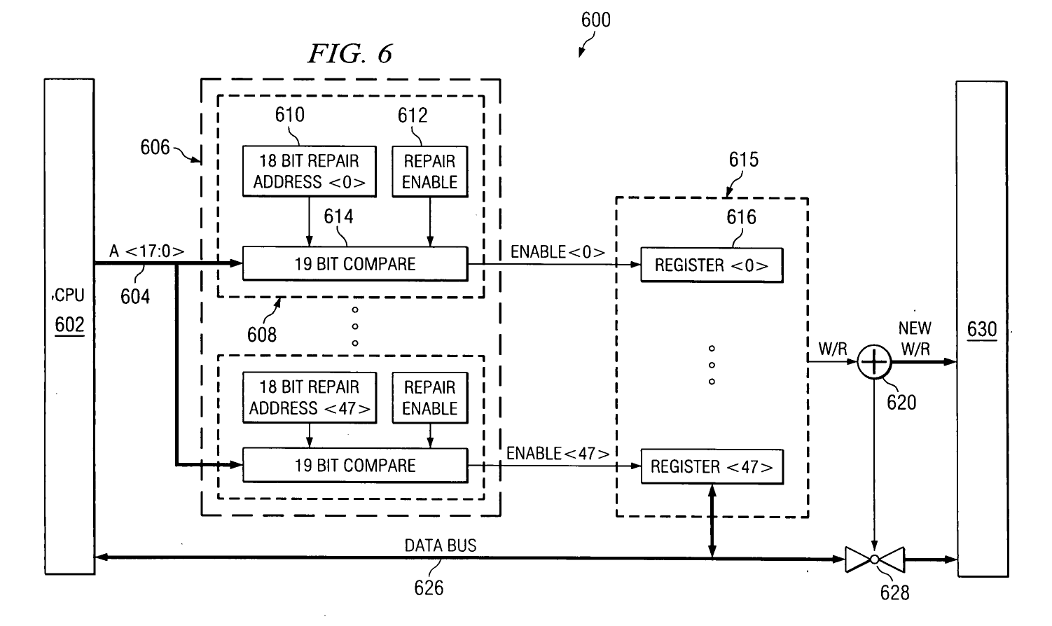

FIG. 6 is a block diagram illustrating a direct mapped repair cache system 600 in accordance with an aspect of the present invention. The system 600 is operable to correct for faulty memory cells by having redundant memory cells located in a repair registers, which are accessed instead of the faulty memory cells for read/write operations. By employing repair registers, storage requirements for addressing repair registers can be reduced compared with conventional row, column, and/or block repair mechanisms. Furthermore, the reduced storage requirements mitigate die area employed for repairing/correcting faulty memory cells.

It is noted that for memory operation, a memory device generally receives memory addresses and provides contents for the memory addresses for read operations and stores contents for the memory addresses for write operation. As an example, a memory device having 256 k 32-bit memory locations has a storage capacity of 8 Mbits. In order to address the memory locations, an 18-bit pointer (memory address) is required. During operation a CPU uses an 18-bit pointer and retrieves a 32-bit number from the memory device for a read operation. For a write operation, the CPU again uses an 18-bit pointer but also provides a 32-bit number which the memory device stores at the memory location referenced by the 18-bit pointer.

The system 600 includes a central processor unit 602, a verification router 606, a repair register bank 615, a main memory 630, and a data bus 626. For illustrative purposes, the system 600 is described with an 18 bit memory address scheme, however it is appreciated that the present invention contemplates other suitable bit sized addressing schemes.

The central processor unit 602 is generally operable to access memory locations of the main memory 630 by memory addresses in order to read to and write from addressed memory locations. It is appreciated that the central processor unit 602 performs other processor related functions and can be one of a number of processors present in an electronic device. The central processor unit 602, as well as some or all of the system 600, can be part of an electronic device such as, but not limited to, a personal computer, a personal digital assistant, a mobile/cellular telephone, a laptop computer, a notebook computer, a digital camera, and the like.

The verification router 606 includes a series or list of individual repair locations 608 and a series or list of comparators 614. The verification router 606 routes read and write requests according to memory addresses and repair information to repair registers or main memory. The number of repair locations 608 is implementation dependent and can vary in accordance with the present invention. Each repair location comprises one or more bits (e.g., 16, 32, or 64) and typically matches the number of bits employed as a word in the main memory 630. The number of comparators is equal to the number of repair locations. As an example, 48 repair locations and 48 comparators are suitable for the exemplary 18 bit memory address scheme. The individual repair locations 608 respectively comprise a repair address 610 and a repair enable indicator 612 and are typically comprised of non-volatile memory. However, it is appreciated that the present invention contemplates employing non-volatile memory for the repair locations. The repair address 610 contains the same number of bits employed in the addressing scheme, which for the 18 bit memory address scheme is also 18 bits. The repair enable indicator 612 typically comprises a single bit that indicates whether the repair location is valid (e.g., active or in use).

The comparators 614 operate in parallel and receive incoming addresses. Individual comparators are associated with individual repair locations 608. On receiving an address, the individual comparators perform a bit by bit comparison of the received address with the corresponding repair address 610 and also check the repair enable indicator 612. If the received address matches the corresponding repair address 610 and is also enabled or valid, as indicated by the repair enable indicator 612, a match is identified and an enable signal is generated.

The repair data bank 614 includes a series or list of repair registers 616. The number of registers 616 present are typically equal to the number of repair locations 608. The repair registers 616 are typically comprised of non-volatile memory, however the present invention also contemplates the registers 616 being comprised of volatile memory. The repair registers 616 are selectably enabled according to enable signals provided by the verification router 606. On being enabled for a write operation, the enabled register is connected to the data bus 626 in order to receive the write data and the main memory 630 is blocked from the data bus 626. The CPU 602 provides the write data to the data bus. On being enabled for a read operation, the enabled register is similarly connected to the data bus in order to provide the read data and the main memory 630 is blocked from the data bus. The CPU 602 obtains the read data from the data bus.

A repair mode circuit 620 is present and is coupled to the verification router 606 and the main memory 630. The repair mode circuit 620 receives the enable signals generated by the verification router 606 and blocks or allows access of the main memory 630 to the data bus 626 by a switch 628. Generally, if all of the enable signals are OFF, which indicates that a match did not occur and that the memory address is not associated with a repair register 616, the repair mode circuit 620 causes a regular memory operation to occur. Otherwise, the repair mode circuit 620 blocks the main memory 630 and allows a repair memory operation to occur.

Upon initiation of a read/write operation, the central processor unit 602 provides a memory address associated with a memory location to write data to and/or read data from. The verification router 604 compares the memory address to the list of repair addresses 610 via the list of comparators 614. On identifying a valid match, the matching comparator provides an enable signal as ON to an associated repair register 616 of the repair register bank 615. Enable signals are also provided to the repair mode circuit 620 which blocks read/write access to the main memory 630. The associated repair register 616 is then connected to the data bus 626 and is employed for the read/write operation. On not identifying a valid match, the enable signals are turned OFF and provided to the repair mode circuit 620 and the repair register bank 615. The repair mode circuit 620 enables access of the main memory 630 by the switch 628 for the read/write operation. The repair register bank 615 is denied access to the data bus 626 because none of its registers are enabled, in this case.

FIG. 6 is illustrated with examples having specific bit lengths and address lengths in order to facilitate a better understanding of the present invention. It is appreciated that present invention is contemplated as being employed for any suitable bit sizes, memory address size, number of repair regions, and the like. Additionally, other components can be present in the system such as, sense amps and decoders.

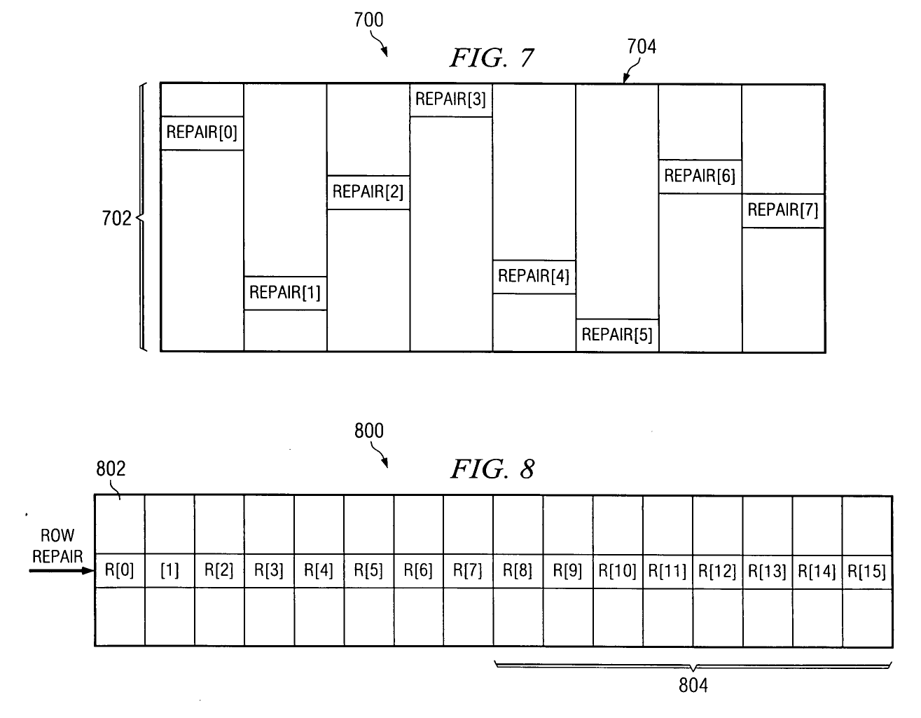

FIG. 7 is a diagram illustrating an exemplary repair register bank 700 in accordance with an aspect of the present invention. The register bank 700 is depicted as having eight repair registers or data locations 704 for illustrative purposes only. It is appreciated that register banks in accordance with the present invention can have a greater or lesser number of repair registers. The repair registers 704 have a bit size or width 702 that typically comprises a memory word (e.g., 8, 16, 32, and 64 bits) in an associated memory device. Individual repair registers 704 can be employed to repair or replace individual memory words of a main memory (not shown) thereby correcting faulty memory locations/cells. It is appreciated that for a memory device that includes a main memory and a repair register bank, that the number of repair registers employed is a function of the number of faulty/defective memory locations. As a result, in operation, zero or more of the repair registers 704 can be employed. Generally, the number of repair registers are selected so as to replace or repair an expected or estimated number of faulty memory locations within given memory devices.

FIG. 8 is a diagram illustrating an exemplary row repair 800 in accordance with an aspect of the present invention. For this example, a single faulty row 800 of a memory array comprises sixteen 32-bit memory words for a total of 512 bits. In order to correct the faulty row, sixteen memory words require replacement. Thus, sixteen repair registers 802 can be employed to repair/replace the sixteen words in the faulty memory row. The repair registers 802 have a width or bit size 804 that matches the memory words of the array, which in this example is 32 bits. Furthermore, an exemplary repair register bank comprising 48 repair registers can be employed to repair three entire faulty rows comprised. It is appreciated that the diagram of FIG. 8 is presented for illustrative purposes and that the present invention includes other row lengths, such as 1024 bits, 32 words, different word sizes, differing numbers of repair registers, and differing numbers of bit sizes for the repair registers. It is further appreciated that column repairs are performed in a similar manner and are, therefore, contemplated in accordance with the present invention.

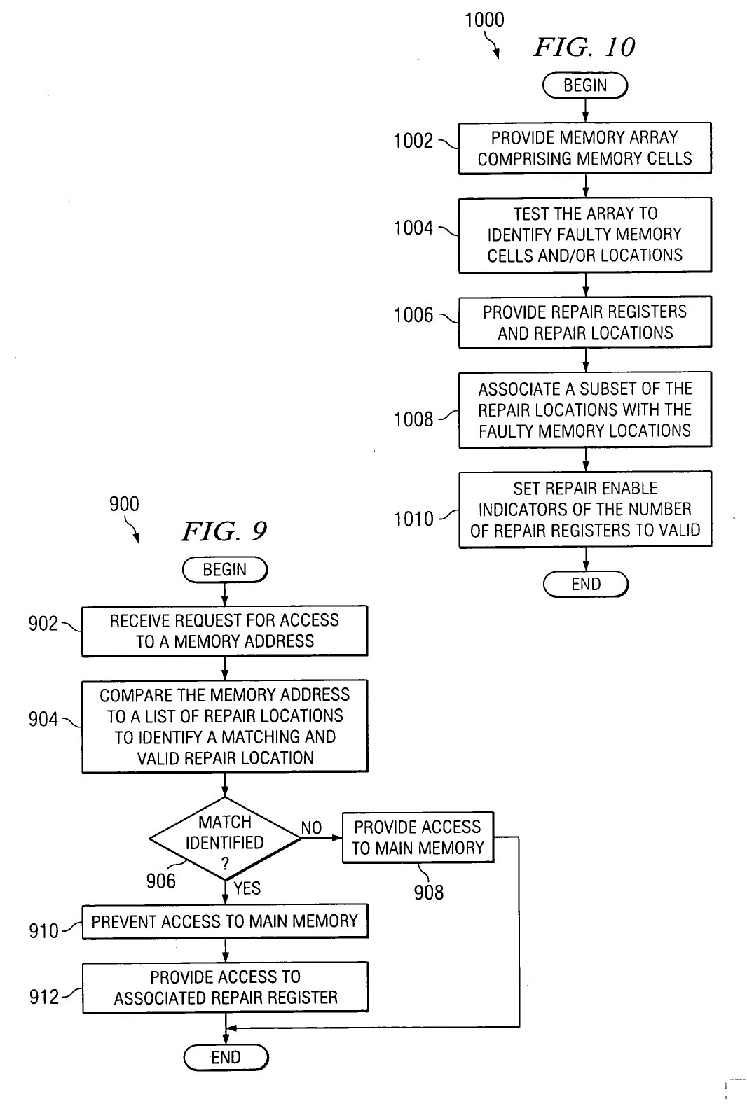

In view of the foregoing structural and functional features described above, methodologies in accordance with various aspects of the present invention will be better appreciated with reference to the above figures. While, for purposes of simplicity of explanation, the methodologies of FIGS. 9 and 10 are depicted and described as executing serially, it is to be understood and appreciated that the present invention is not limited by the illustrated order, as some aspects could, in accordance with the present invention, occur in different orders and/or concurrently with other aspects from that depicted and described herein. Moreover, not all illustrated features may be required to implement a methodology in accordance with an aspect the present invention.

FIG. 9 is a flow diagram illustrating a method 900 of operating a direct mapped repair cache in accordance with an aspect of the present invention. The method 900 can be employed to correct for faulty memory locations within a main memory by selectively routing read/write requests to a repair register bank for memory addresses that correspond to faulty memory locations within main memory. The main memory includes a number of memory locations of a fixed size and addressable by the memory address. The repair register bank comprises repair registers that can store and provide information content in place or instead of faulty memory locations.

The method 900 begins at block 902 wherein a request for access to a memory address is received. The request includes read and/or write access to the memory address. Typically, a processor or other electronic device initiates the request.

Subsequently, the memory address is compared to a list of repair locations at block 904 in order to identify a matching and valid repair location. The list of repair locations is stored in memory, typically non-volatile memory, and individually include a repair address and a repair enable indicator. The repair address has the same width or bit size as the memory address and the repair indicator can simply be a single bit, indicating whether the repair address is valid. It is noted that a repair location can match the memory address, bit by bit, but not be a valid repair location for the memory address if the repair indicator indicates that it is not a valid repair location.

If a valid match is not identified at decision block 906, access to the main memory by a requestor is provided at block 908. Accordingly, a memory location associated with the memory address has not been identified as faulty and content can be written to the memory location for a write operation and read from the memory location for a read operation. Generally, a data bus is present and connected to the main memory. Then, the main memory provides access to the associated memory location according to the memory address.

If a valid match is identified at decision block 906, access to the main memory by the requester is prevented at block 910. One suitable mechanism for preventing access is by employing a repair mode circuit and/or switch that isolates the main memory from the data bus. Additionally, the memory address is not provided to the main memory. Continuing at block 912, access to a repair register associated with the matching repair location is provided for the requester. Generally, a repair register is present and associated with each repair location within the list of repair locations.

The sizes for memory addresses, memory locations, repair address, repair indicator, and repair locations can vary on implementation from above provided examples and still be in accordance with the method 900 and the present invention.

FIG. 10 is a flow diagram illustrating a method 1000 of configuring a repair cache system in accordance with an aspect of the present invention. The method 1000 is be employed to test and identify faulty memory cells and locations located within a memory array and configure the repair cache system so that repair locations are employed in place of identified faulty memory locations. The method 1000 is described with respect to a single memory array for illustrative purposes, but can be employed for portions of an array and/or multiple memory arrays and still be in accordance with the present invention.

The method 1000 begins at block 1002 wherein a memory array comprising a number of memory cells and memory locations is provided. The memory cells can be single bit memory cells and/or multi bit memory cells. The memory locations comprise a number of cells or bits, such as a word (e.g., 16 bits).

The memory array is tested at block 1004 in order to identify faulty memory locations. The identified faulty memory locations are those memory locations that have one or more faulty memory cells. It is noted that the method 1000 also contemplates not identifying any faulty memory cells.

Repair registers and repair locations are provided at block 1006, wherein individual repair registers are associated with individual repair locations. The number of repair registers and repair locations is typically, but not always, fixed and is generally selected according to an estimated and/or expected number of faulty memory locations. The repair registers typically comprise at least the same number of bits as the memory locations. The repair locations comprise a repair address portion and a repair indicator.

The identified faulty memory locations are associated with a list or subset of the repair locations at block 1008 by inserting memory addresses of the identified faulty memory locations into the repair address portions of the subset of repair locations. Further, at block 1010, the repair indicators of the associated subset of repair locations are set to valid. Repair indicators of non-associated repair locations can be set to invalid. Thus, each repair location within the subset has a repair address associated with one of the identified faulty memory locations and a repair indicator set to valid.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

What is claimed is:

1. A repair cache system comprising:
a main memory comprising identified valid memory locations and identified faulty memory locations;
a repair component comprising repair registers associated with the faulty memory locations; and
a repair verification router comprising repair locations associated with the faulty memory locations, wherein the repair verification router routes read/write requests for faulty memory locations to the repair component and routes read/write requests for identified valid memory locations to the main memory.

2. The system of claim 1, wherein the main memory is comprised of ferroelectric memory cells.

3. The system of claim 1, wherein the repair locations respectively comprise a repair address.

4. The system of claim 1, wherein the repair locations respectively comprise a repair address and a repair enable indicator.

5. The system of claim 3, wherein the repair addresses comprise memory addresses of identified faulty memory locations.

6. The system of claim 1, wherein the memory locations and the repair registers have a size of 16-bits.

7. The system of claim 1, wherein the memory locations have a size of 32-bits.

8. The system of claim 3, wherein the repair addresses and memory addresses of the memory locations have a size of 18 bits.

9. The system of claim 1, wherein the verification router further comprises a non-volatile memory for maintaining the repair locations.

10. The system of claim 9, wherein the verification router further comprises a comparator that compares a memory address of a read/write request to repair locations to identify a match that routes the read/write request to the repair component.

11. A direct mapped repair cache system comprising:
a repair verification component comprising a list of repair locations and a list or comparators;
a repair register bank comprising a list of repair registers;
a main memory comprising identified valid memory locations and identified faulty memory locations;
a data bus selectively coupled to the repair register bank and the main memory; and
wherein the repair verification component compares a memory address of a read/write request to the list of repair locations with the list of comparators to identify a match, couples a matching repair register of the repair register bank to the data bus on identifying a match, and couples the main memory to the data bus on not identifying a match.

12. The system of claim 11, wherein the repair registers respectively comprise a repair address equal to a memory address of associated memory locations.

13. The system of claim 11, wherein the repair registers respectively comprise a repair address and a repair enable indicator, wherein the repair enable indicator is set to valid on the repair address being a memory address of a faulty memory location.

14. The system of claim 11, wherein the list of comparators identify a match by comparing repair addresses of the list of repair locations with memory address in parallel.

15. A method of operating a direct mapped repair cache comprising:
receiving a request for read/write access to a memory address;
comparing the memory address to a list of repair locations to identify a matching and valid repair location;
on failure to identify a matching and valid repair location, providing read/write access to a memory location in main memory addressed by the memory address; and
on identifying a matching and valid repair location, preventing read/write access to main memory and providing read/write access to a repair register associated with the matching and valid repair location.

16. The method of claim 15, comparing the memory address to the list of repair locations comprising performing a bitwise comparison of the memory address to repair addresses of the list of repair locations.

17. The method of claim 15, wherein the matching and valid repair location has a repair enable indicator set to valid.

18. The method of claim 15, wherein providing read/write access to the repair register comprises coupling a data bus to the repair register.

19. A method of configuring a repair cache system comprising:
providing a memory array comprising memory locations;
testing the memory array to identify faulty memory locations and identify valid memory locations; and
associating repair registers and repair locations to the identified faulty memory locations, wherein the repair registers are individually associated to the repair locations.

20. The method of claim 19, wherein associating the repair registers and repair locations to the identified faulty memory locations comprises setting repair addresses of the repair locations to memory addresses of the identified faulty memory locations.

21. The method of claim 19, further comprising setting repair enable indicators of the associated repair registers to valid.

22. The method of claim 19, wherein the associated repair locations are a subset of possible repair locations.
